(19) United States
(12) Patent Application Publication
(10) Pub. No.: US 2020/0328749 A1
(43) Pub. Date: Oct. 15, 2020

(54) PHASE-FREQUENCY DETECTOR

(71) Applicant: BAE SYSTEMS Information and Electronic Systems Integration Inc., Nashua, NH (US)

(72) Inventor: Gary M. Madison, Waltham, MA (US)

(73) Assignee: BAE SYSTEMS Information and Electronic Systems Integration Inc., Nashua, NH (US)

(21) Appl. No.: 16/383,179

(22) Filed: Apr. 12, 2019

(51) Int. Cl. H03L 7/089; H03L 7/08; H03L 7/099

(52) U.S. Cl. CPC H03L 7/0891; H03L 7/099; H03L 7/0807

(57) ABSTRACT

A phase-frequency detector has two latches, two logic gates, and two delay sources. Operation includes inputting a reference clock signal to a first of two latches; inputting a feedback clock signal to a second of two latches; outputting simultaneously a first signal and a second signal. The first signal having a pulse width directly proportional to a phase difference between said reference clock signal and the feedback clock signal; the second signal having a pulse width inversely proportional to the phase difference between the reference clock signal and the feedback clock signal. The outputs of the latches indicate a differential phase difference of signals, thereby increasing the signal-to noise ratio of the phase-frequency detector.

### FIELD OF THE DISCLOSURE

This disclosure relates to phase-locked loops, and, more particularly, to improved signal-to-noise ratio phase-frequency detectors.

### BACKGROUND

A phase-locked loop (PLL) is widely used in many electrical and computer applications to maintain a fixed phase relationship between an input signal and a reference signal. A phase-locked loop typically comprises four main components: a phase-frequency detector, a charge pump, a loop filter, an oscillator (VCO) and a frequency divider. The term “phase detector,” in common (inaccurate) usage, often implies a phase-frequency detector (PFD). However, for accuracy, a pure phase detector is only capable of achieving lock if the frequencies are already very close. Without some additional means provided to get the frequencies close enough to achieve pull-in, phase lock will not be achieved. A PFD, in contrast, performs both functions.

The phase-frequency detector compares the phase and frequency of a reference clock to that from a VCO, directly, buffered, and/or divided in frequency. One of the primary constraints on the achievable noise performance of a phase-locked loop is the signal-to-noise ratio of the phase-frequency detector.

What is needed, therefore, are techniques for improving the signal-to-noise ratio of a phase-frequency detector.

### SUMMARY

An embodiment provides a phase-frequency detector device comprising a plurality of input signals; two latches coupled to the input signals; two logic gates each coupled to one of the latches; and two delay elements; each of the delay elements respectively providing an input to one of the logic gates, and each of the logic gates respectively providing a reset input to each respective latch; wherein outputs of the latches simultaneously indicate a positive and a negative phase difference of the input signals, thereby increasing a signal-to noise ratio of the phase-frequency detector. In embodiments the latches comprise D-type latch circuits. In other embodiments, the logic gates are comprised of NAND gates. In subsequent embodiments the phase-frequency detector device is a component of a phase-locked loop device. For additional embodiments at least one delay element comprises inverters. In another embodiment, at least one delay element comprises RC or RL elements. For a following embodiment at least one delay element comprises transmission lines. In subsequent embodiments at least one delay element comprises optical fibers. In additional embodiments the phase-frequency detector compares a phase and a frequency of a reference clock to that directly from a voltage controlled oscillator. In included embodiments the phase-frequency detector compares a phase and a frequency of a reference clock to that from a buffered voltage controlled oscillator. In yet further embodiments the phase-frequency detector compares a phase and a frequency of a reference clock to that directly from a voltage controlled oscillator and divided in frequency. In related embodiments the phase-frequency detector compares a phase and a frequency of a reference clock to that from a buffered voltage controlled oscillator and divided in frequency. For further embodiments an output gain of the phase-frequency detector is increased by a factor of about two around about a zero phase difference. In ensuing embodiments the noise is deceased by about 3.5 dBc/Hz.

Another embodiment provides a phase-frequency detector system comprising two latches; two logic gates providing a reset signal to the two latches; two delay sources each coupled to one of the two logic gates; a reference clock signal to a first of the two latches; a feedback clock signal to a second of the two latches; outputting simultaneously a first signal and a second signal; the first signal having a pulse width proportionate to a positive phase difference between the reference clock signal and the feedback clock signal; the second signal having a pulse width proportionate to a negative phase difference between the reference clock signal and the feedback clock signal; wherein outputs of the latches indicate a differential phase difference of signals, thereby increasing a signal-to noise ratio of the phase-frequency detector. For yet further embodiments, wherein the phase-frequency detector controls a lock of a phase-lock loop. For more embodiments the latches comprise D-type latches. Continued embodiments include logic gates comprising gates comprise NAND gates. For additional embodiments, at least one delay element comprises at least one of inverters, RC or RL elements, transmission lines, and optical fibers.

A yet further embodiment provides a system for a phase-locked loop comprising a phase-frequency detector comprising two D-latches; two NAND gates with each coupled to one of the D-latches; and two delay elements; wherein each of the delay elements respectively providing an input to one of the NAND gates, and each of the NAND gates respectively providing a reset input to each respective D-latch; the phase-frequency detector having two simultaneous outputs comprising a first signal and a second signal; the first signal having a pulse width proportionate to a positive phase difference between the reference clock signal and the feedback clock signal; the second signal having a pulse width proportionate to a negative phase difference between the reference clock signal and the feedback clock signal; whereby the signal to noise ratio of the phase-frequency detector is increased by increasing a dV per degree rate of the two simultaneous outputs of the phase-frequency detector.

### BRIEF DESCRIPTION OF THE DRAWINGS

FIG. 1 depicts a phase locked loop with a phase-frequency detector configured in accordance with an embodiment.

FIG. 2 is a block diagram illustrating a phase-frequency detector configured in accordance with an embodiment.

FIG. 3 is part of a phase-frequency detector circuit configured in accordance with an embodiment.

FIG. 4 is flow chart of a phase-frequency detector method configured in accordance with an embodiment.

FIG. 5 depicts increased gain pulse trains configured in accordance with an embodiment.

FIG. 6 is a graph of a phase detector in-circuit gain comparison configured in accordance with an embodiment.

FIG. 7 is a graph of a locked VCO noise performance comparison configured in accordance with an embodiment.

These and other features of the present embodiments will be understood better by reading the following detailed description, taken together with the figures herein described. The accompanying drawings are not intended to be drawn to scale. For purposes of clarity, not every component may be labeled in every drawing.

### DETAILED DESCRIPTION

The features and advantages described herein are not all-inclusive and, in particular, many additional features and advantages will be apparent to one of ordinary skill in the art in view of the drawings, specification, and claims. Moreover, it should be noted that the language used in the specification has been selected principally for readability and instructional purposes, and not to limit in any way the scope of the inventive subject matter. The invention is susceptible of many embodiments. What follows is illustrative, but not exhaustive, of the scope of the invention.

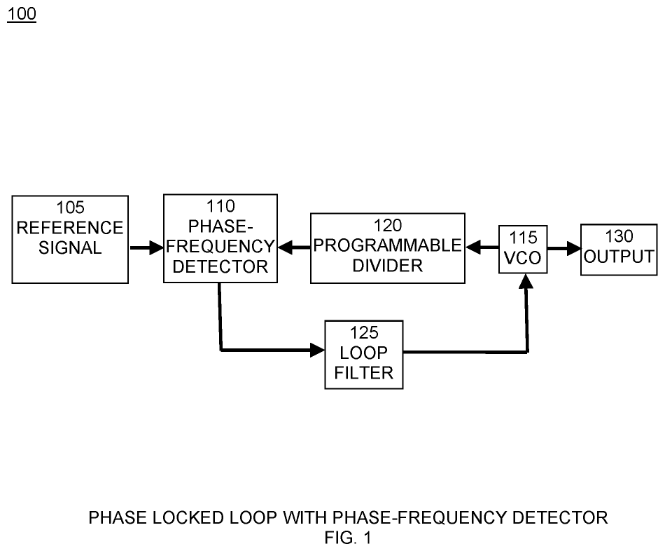

FIG. 1 depicts a phase locked loop 100 with a phase-frequency detector according to one embodiment. Phase lock loop 100 comprises a reference signal 105; a phase-frequency detector 110; a voltage controlled oscillator 115; an optional programmable divider block 120; a loop filter 125; and output 130.

In any PLL (Phase-Locked Loop) application, on chip or board level, embodiments of this PFD design can replace the standard PFD to achieve an improvement in locked VCO noise, and in some applications, a reduction in reference spurious signals on the locked VCO.

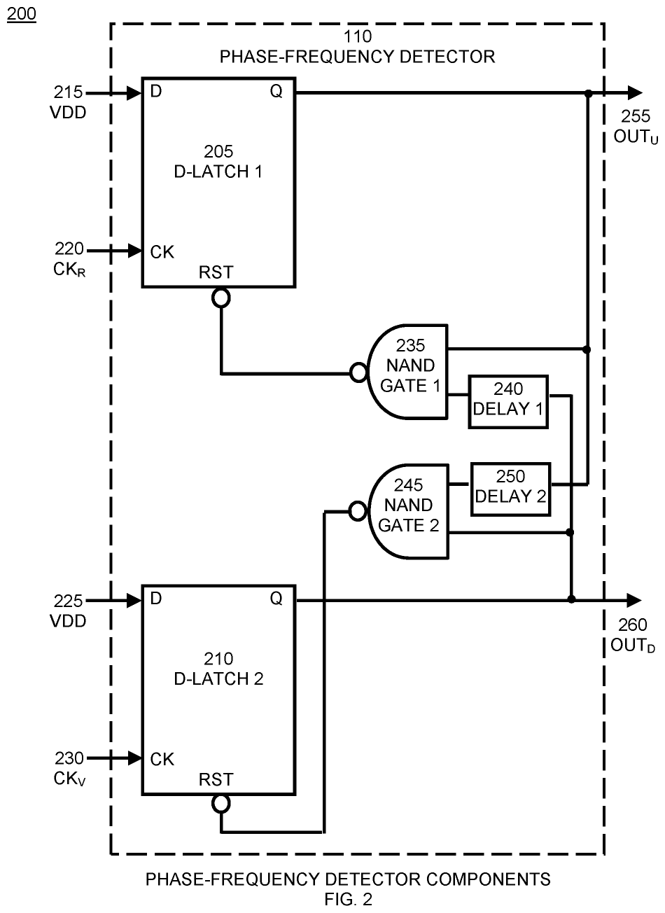

FIG. 2 is a block diagram 200 illustrating a phase-frequency detector 110 in accordance with one embodiment. Phase-frequency detector 110 components comprise first D-Latch 1 205 and second D-Latch 2 210. Inputs to D-Latch 1 205 comprise VDD 215 and CK_{R} 220. Inputs to D-Latch 2 210 comprise VDD 225 and CK_{V} 230. First NAND gate 1 235 provides input to RST of D-Latch 1 205. Inputs to NAND gate 1 235 comprise Q output from D-Latch 1 205 and output from first Delay 1 240. Input to Delay 1 240 comprises Q output from D-Latch 2 210. Second NAND gate 2 245 provides input to RST of D-Latch 2 210. Inputs to NAND gate 2 245 comprise Q output from D-Latch 2 210 and output from second Delay 2 250. Input to Delay 2 250 comprises Q output from D-Latch 1 205. Phase-frequency detector 110 outputs comprise OUT_{U} 255 from Q output from D-Latch 1 205 and OUT_{D} 260 from Q output from D-Latch 2 210.

The Q outputs (Q) of the Latches 205 and 210 are coupled to NAND gates 235 and 245 to reset the Latches 205 and 210 after the Latches have been triggered by the first and second signals. Latch circuits 205 and 210 are D-type latches that each include a D-type input terminal (D), a clock input terminal (CK), a Q output terminal (Q). PFD embodiments yield a significant improvement in signal-to-noise ratio, in any given technology, over existing designs.

In nonlimiting embodiments Delay 1 and 2 elements are implemented by resistor/capacitor (RC), resistor/inductor (RL), transmission line, or optical fiber elements. RC circuits comprise resistors and capacitors driven by a voltage source. Delay is implemented through the charging and discharging of the capacitor component(s) through the resistor component(s). RL circuits comprise resistors and inductors driven by a voltage source. Here, delay is implemented through the varying voltage applied to the inductor, where the total current in the RL circuit lags the source voltage. A transmission line serves as a delay element by the propagation delay of the signal along the length of the transmission line. Similarly, optical fiber delay elements provide delay based on the propagation time of light along the length of the optical fiber.

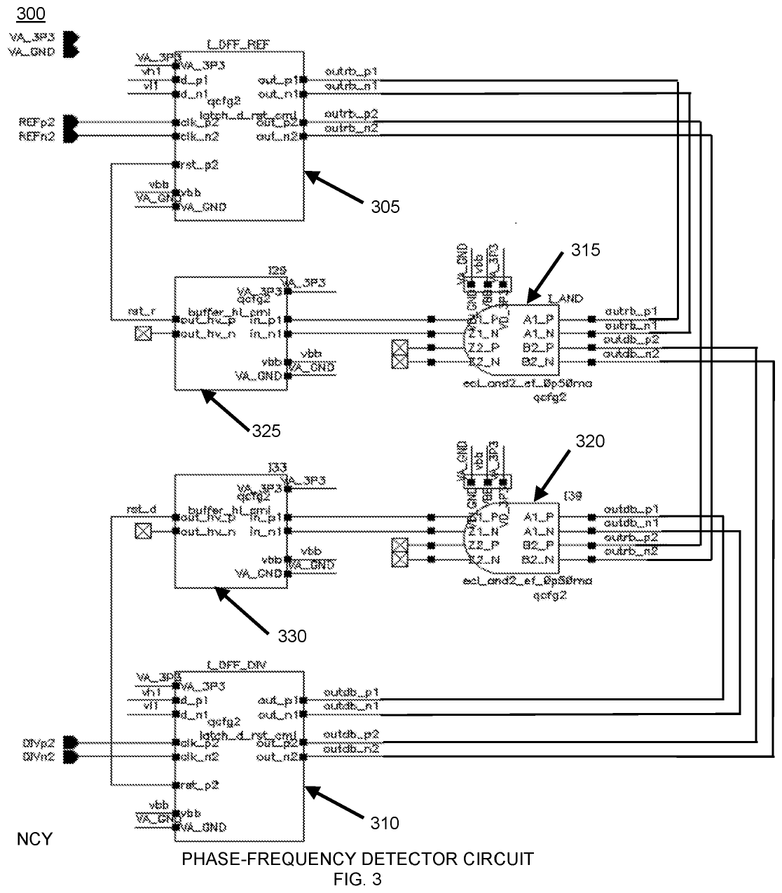

FIG. 3 is part of a phase-frequency detector circuit 300.

Embodiments use on-chip devices; however, any combination of components would function. Depicted are first and second D-Latches 305 and 310; first and second (N)AND Gates 315 and 320; and first and second buffers 325 and 330. Embodiments of the circuit rely on the inherently larger AND-gate delay from the “2” inputs with “1” inputs to cause the reference and divide pulses to both be changing (in opposite directions) at crossover to raise the PFD gain.

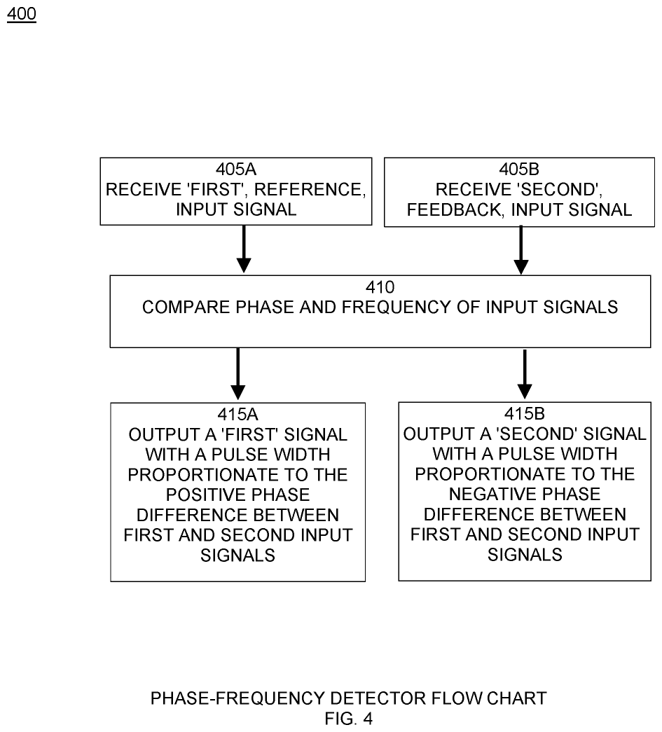

FIG. 4 is a flow chart of a phase-frequency detector method 400 according to one embodiment. Steps comprise receiving a ‘first’, reference, input signal 405A while simultaneously receiving a ‘second’, feedback, input signal 405B; comparing both the phase and the frequency of the input signals 410; simultaneously outputting a ‘first’ pulse train signal with a pulse width proportionate to the positive phase difference between the first and the second input signals 415A; and outputting a ‘second’ pulse train signal with a pulse width proportionate to the negative phase difference between the first and the second input signals 415B. The outputs yield a significant improvement in signal-to-noise ratio, and in embodiments, a reduction in reference spurious signals on the locked VCO.

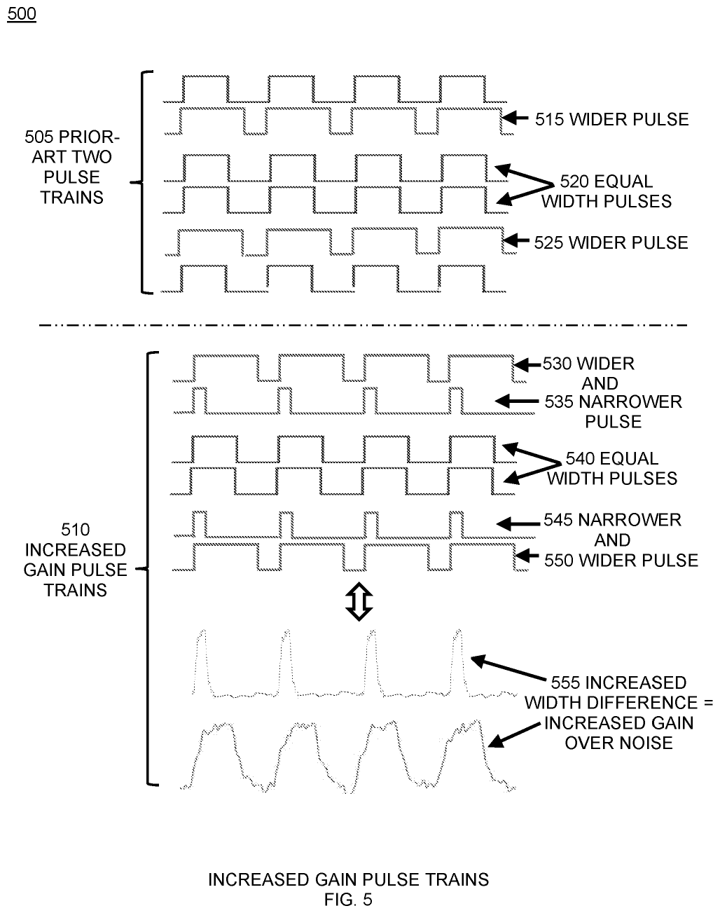

FIG. 5 depicts increased gain pulse trains 500 according to one example versus prior art pulse trains. For comparison, prior art two pulse train outputs are shown 505. An embodiment's increased gain pulse train outputs are also shown 510. For the prior art two pulse trains 505, when the clock input phases vary from equality, the widths of the pulses in one—and only one—of the pulse trains will increase, proportionally 515, 525. When the clock input phases are equal, the output pulses are identical 520. The gain (the change in the averaged difference voltage between these two pulse trains), as a function of clock phase difference change, will remain constant through 0 phase. For increased gain phase-frequency detector pulse train output embodiments 510, as the phase difference departs from 0, not only do the widths of the pulses in one pulse train increase 530, 550, the widths of the pulses in the other train decrease 535, 545, resulting in a significant increase in gain. When the clock input phases are equal, the output pulses are identical 540. As depicted by the embodiment pulse trains with noise 555, embodiments provide an increase in gain (×2) over the standard PFD in the critical region around 0 phase difference, with only a minimal increase in noise, thereby resulting in an improved signal-to-noise ratio, and it achieves this with only a slight (approximately 25%) increase in complexity and power consumption. The delay elements accomplish this improved signal-to-noise ratio by increasing the in-lock pulse widths from both PFD outputs in a manner that, when there is a small phase difference, the pulse widths from one output increase, while those from the other output decrease. By contrast, with the same small phase difference in known PFDs, the pulse widths from one output increase, while those from the other remain unchanged. Since the pulse repetition rate is constant, determined by the operating frequency, the average output voltage and gain is proportional to the pulse width. Importantly, while the gain may be approximately doubled, the noise, mostly due to the different delay elements, does not increase anywhere near that amount. Hence, an increase in signal-to-noise ratio is obtained. For embodiments, the method of producing the delay is not critical; however, it should be done in a manner that does not add significant noise. The greater the delay, the wider the higher gain region plotted against the input phase difference. As the delay shrinks toward zero, the higher-gain region narrows and eventually vanishes.

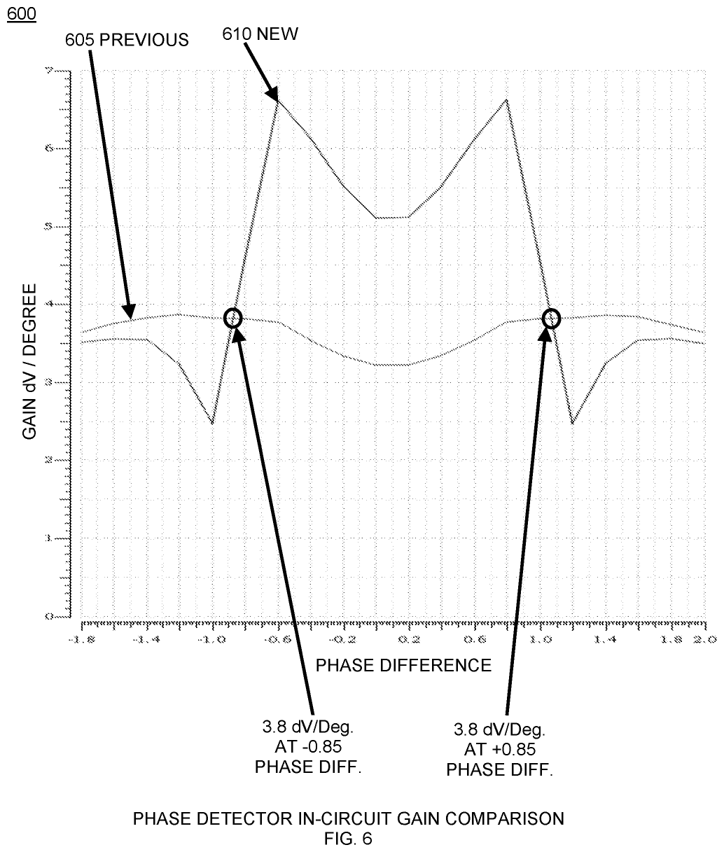

FIG. 6 is a graph 600 of a phase detector in-circuit gain comparison according to one example. Gain is output voltage change per degree, plotted vs phase difference. In normal operation, the loop maintains a 0-degree phase difference. Gain comparison graph 600 plots phase difference versus gain in dV per degree. Previous gain 605 is between 3.2 and 3.8 dV/degree within a phase difference of −1.8 to +2.0. In contrast, new gain 610 is between 3.8 and 6.6 dV/degree within a phase difference of −0.85 to +0.85.

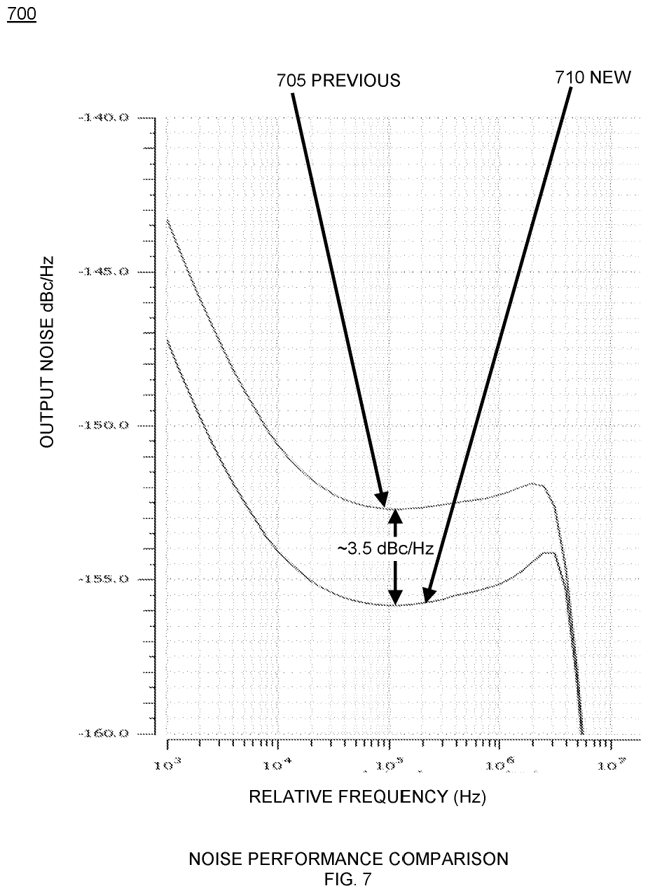

FIG. 7 is a graph 700 of a locked VCO noise performance comparison. These are plots of the locked VCO noise in dBc/Hz vs distance from the carrier. Previous output locked VCO noise curve 705 shows an approximate 3.5 dBc/Hz greater output noise than new phase-frequency detector locked VCO noise curve 710 at a relative frequency of between about 10⁴ and about 10⁶ Hz.

The block diagrams in the Figures illustrate the architecture, functionality, and operation of possible implementations of systems, methods, and computer program products according to various embodiments of the present invention. In this regard, each block in the block diagrams may represent a module, segment, or portion of instructions, which comprises one or more executable instructions for implementing the specified logical function(s). It will also be noted that each block of the block diagrams and combinations of blocks in the block diagrams, can be implemented by special purpose hardware-based systems that perform the specified functions or acts or carry out combinations of special purpose hardware and computer instructions.

The foregoing description of the embodiments has been presented for the purposes of illustration and description. It is not intended to be exhaustive or to limit the invention to the precise form disclosed. Many modifications and variations are possible in light of this disclosure. It is intended that the scope of the present disclosure be limited not by this detailed description, but rather by the claims appended hereto.

A number of implementations have been described. Nevertheless, it will be understood that various modifications may be made without departing from the scope of the disclosure. Although operations are depicted in the drawings in a particular order, this should not be understood as requiring that such operations be performed in the particular order shown or in sequential order, or that all illustrated operations be performed, to achieve desirable results.

Each and every page of this submission, and all contents thereon, however characterized, identified, or numbered, is considered a substantive part of this application for all purposes, irrespective of form or placement within the application. This specification is not intended to be exhaustive or to limit the invention to the precise form disclosed. Many modifications and variations are possible in light of this disclosure. Other and various embodiments will be readily apparent to those skilled in the art, from this description, figures, and the claims that follow. It is intended that the scope of the invention be limited not by this detailed description, but rather by the claims appended hereto.

1. A phase-frequency detector device comprising:
a plurality of input signals;
a first latch and a second latch, wherein each of the first and second latches are coupled to one of the plurality of input signals;
a first logic gate and a second logic gate, wherein each of the first and second logic gates are coupled to one of the first and second latches; and
a first delay element and a second delay element,
wherein each of the first and second delay elements provide an input to one of the first and second logic gates,
wherein each of the first and second logic gates provide a reset input to each respective first and second latches,
wherein the input of the first delay element includes a Q output from the second latch and the input of the second delay element includes a Q output from the first latch,
wherein outputs of the first and second latches simultaneously indicate a positive and a negative phase difference of said input signals, thereby increasing a signal-to noise ratio of the phase-frequency detector.

2. The device of claim 1, wherein the first and second latches comprise D-type latch circuits.

3. The device of claim 1, wherein the first and second logic gates are comprised of NAND gates.

4. The device of claim 1, wherein the phase-frequency detector device is a component of a phase-locked loop device.

5. The device of claim 1, wherein at least one of the first and second delay elements comprises inverters.

6. The device of claim 1, wherein at least one of the first and second delay elements comprises RC or RL elements.

7. The device of claim 1, wherein at least one of the first and second delay elements comprises transmission lines.

8. The device of claim 1, wherein at least one of the first and second delay elements comprises optical fibers.

9. The device of claim 1, wherein the phase-frequency detector compares a phase and a frequency of a reference clock to that directly from a voltage controlled oscillator.

10. The device of claim 1, wherein the phase-frequency detector compares a phase and a frequency of a reference clock to that from a buffered voltage controlled oscillator.

11. The device of claim 1, wherein the phase-frequency detector compares a phase and a frequency of a reference clock to that directly from a voltage controlled oscillator and divided in frequency.

12. The device of claim 1, wherein the phase-frequency detector compares a phase and a frequency of a reference clock to that from a buffered voltage controlled oscillator and divided in frequency.

13. The device of claim 1, whereby an output gain of the phase-frequency detector is increased by a factor of about two around about a zero phase difference.

14. The device of claim 1, wherein the noise is deceased by about 3.5 dBc/Hz.

15. A phase-frequency detector system comprising:
a first latch and a second latch;
a first logic gate and a second logic gate, wherein the first and second logic gates provide a reset signal to the first and second latches;
a first delay source and a second delay source, wherein the input of the first delay source includes a Q output from the second latch and the input of the second delay source includes a Q output from the first latch,
a reference clock signal coupled to the first latch;
a feedback clock signal coupled to the second latch;
outputting simultaneously a first signal and a second signal;
wherein the first signal has a pulse width proportionate to a positive phase difference between the reference clock signal and the feedback clock signal;
wherein the second signal has a pulse width proportionate to a negative phase difference between the reference clock signal and the feedback clock signal;
wherein outputs of the first and second latches indicate a differential phase difference of signals, thereby increasing a signal-to noise ratio of the phase-frequency detector.

16. The system of claim 15, wherein the phase-frequency detector controls a lock of a phase-lock loop.

17. The system of claim 15, wherein the first and second latches comprise D-type latches.

18. The system of claim 15, wherein the first and second logic gates comprise NAND gates.

19. The system of claim 15, wherein at least one of the first and second delay sources comprises at least one of inverters, RC or RL elements, transmission lines, and optical fibers.

20. A system for a phase-locked loop comprising:
a phase-frequency detector comprising:
a first D-latch and a second D-latch;
a first NAND gate and a second NAND gate, wherein each of the first and second NAND gates are coupled to one of the first and second D-latches; and
a first delay element and a second delay element,
wherein each of the first and second delay elements respectively provide an input to one of the first and second NAND gates,
wherein each of the first and second NAND gates respectively provide a reset input to each respective first and second D-latch;
wherein the input of the first delay element includes a Q output from the second latch and the input of the second delay element includes a Q output from the first latch,
wherein the phase-frequency detector has two simultaneous outputs comprising a first signal and a second signal;
wherein the first signal has a pulse width proportionate to a positive phase difference between the reference clock signal and the feedback clock signal;
wherein the second signal has a pulse width proportionate to a negative phase difference between the reference clock signal and the feedback clock signal; and
wherein the signal to noise ratio of the phase-frequency detector is increased by increasing a dV per degree rate of the two simultaneous outputs of the phase-frequency detector.
